(19) United States
(12) Patent Application Publication
(10) Pub. No.: US 2025/0035807 A1
(43) Pub. Date: Jan. 30, 2025

(54) PROXIMITY DETECTION CIRCUIT AND PROXIMITY DETECTION METHOD WITH COMPENSATION

(71) Applicant: SENSORTEK TECHNOLOGY CORP., Hsinchu County (TW)

(72) Inventors: Wang-An Lin, Hsinchu County (TW); Chih-Yu Lin, Hsinchu County (TW); Chih-Yu Joe Lin, Hsinchu County (TW)

(21) Appl. No.: 18/601,103

(22) Filed: Mar. 11, 2024

Related U.S. Application Data
(60) Provisional application No. 63/450,985, filed on Mar. 9, 2023.

(51) Int. Cl. G01V 3/08

(52) U.S. Cl. CPC G01V 3/088; H03K 17/955

(57) ABSTRACT

The present application provides a proximity detection circuit and a proximity detection method with compensation. The proximity detection circuit comprises a detection circuit, a baseline processing circuit and a proximity sensing circuit. The detection circuit generates a detection data and a reference data. The proximity sensing circuit generates a proximity signal according to a proximity threshold, the detection data and a baseline data generated from the baseline processing circuit, and the proximity detection circuit and the proximity detection method compensate the baseline data or the proximity threshold according to the reference data. The condition of misjudgment may be avoided under the influence of environmental factors.

### FIELD OF THE INVENTION

The present application related to a circuit and a method for detection, in particular to a proximity detection circuit and a proximity detection method with compensation for reducing misjudgment due to environmental factors.

### BACKGROUND OF THE INVENTION

With the advancement of technology, people are closely related to electronic devices (such as mobile phones, tablet computers, etc.) in life or work. Most modern electronic devices have a variety of sensors, for example, proximity sensors, ambient light sensors, temperature sensors, to assist various functions of electronic devices, such as reducing RF power when the human body is close to the electronic device, automatically adjusting the screen brightness according to the ambient light brightness, and adjusting the operating mode according to the temperature of the electronic device.

Proximity sensors are sensors that may detect whether a human body is close to an electronic device without touching the human body. Capacitive proximity sensors are currently widely used in electronic devices. The electronic device has a sensing electrode, which is equivalent to a capacitor. The equivalent capacitance of the sensing electrode will be changed under the influence of the human body and objects. The proximity sensor senses the change in the equivalent capacitance of the sensing electrode. Then it may be known whether the human body or object is close to the electronic device. However, environmental factors, such as the temperature of the electronic device, the ambient temperature, or humidity, will affect the capacitance. As a result, the proximity sensors according to the prior art might be affected by environmental factors and misjudgment may occur, such as misjudgment of a proximity events. To this day, the industry is still eager to finding ways to reduce misjudgments and improve the accuracy of proximity sensing.

To solve the above problem according to the prior art, the present application provides a proximity detection method and a proximity detection circuit for reducing misjudgment due to the influence of environmental factors on the proximity sensor.

### SUMMARY OF THE INVENTION

An objective of the present application is to provide a proximity detection method and a proximity detection circuit, which generates a proximity signal according to detection data, baseline data, and a proximity threshold for detecting proximity events. Further, compensate the baseline data or the proximity threshold according to reference data corresponding to environmental factors for reducing misjudgment due to the influence of environmental factors on the proximity sensor and enhancing the accuracy of proximity sensing.

The present application provides a proximity detection method, which detects a reference electrode to give reference data. Next, generate a proximity signal according to detection data, baseline data, and a proximity threshold and correct the baseline data according to the reference data. By correcting the baseline data according to the reference data corresponding to environmental factors, the problem of misjudgment due to the influence of environmental factors may be reduced.

The present application further provides a proximity detection circuit, which comprises a detection circuit, a baseline processing circuit, and a proximity sensing circuit. The detection circuit generates detection data and reference data. The baseline processing circuit generates baseline data and corrects the baseline data according to the reference data. The proximity sensing circuit generates a proximity signal according to the detection data, the baseline data, and a proximity threshold. The proximity signal is used to represent if a human body is proximate or away from an electronic device. By correcting the baseline data according to the reference data corresponding to environmental factors, the problem of misjudgment due to the influence of environmental factors may be reduced.

The present application further provides a proximity detection method, which detects a reference electrode and generate reference data. Then, generate a proximity signal according to detection data, baseline data, and a proximity threshold and correct the proximity threshold according to the reference data. By correcting the proximity threshold according to the reference data corresponding to environmental factors, the problem of misjudgment due to the influence of environmental factors may be reduced.

The present application further provides a proximity detection circuit, which comprises a detection circuit, a baseline processing circuit, a threshold processing circuit, and a proximity sensing circuit. The detection circuit generates detection data and reference data. The baseline processing circuit generates baseline data according to the detection data. The threshold processing circuit generates a proximity threshold according to the reference data. The proximity sensing circuit generates a proximity signal according to the detection data, the baseline data, and the proximity threshold. The proximity signal is used to represent if a human body is proximate or away from an electronic device. By correcting the proximity threshold according to the reference data corresponding to environmental factors, the problem of misjudgment due to the influence of environmental factors may be reduced.

### BRIEF DESCRIPTION OF DRAWINGS

FIG. 1 shows a block diagram of the proximity detection circuit according to an embodiment of the present application;

FIG. 2 shows a flowchart of the proximity detection method according to an embodiment of the present application;

FIG. 3 shows a schematic diagram of compensating the baseline data according to an embodiment of the present application;

FIG. 4 shows a flowchart of the proximity detection method according to another embodiment of the present application;

FIG. 5 shows a block diagram of the proximity detection circuit according to another embodiment of the present application;

FIG. 6 shows a block diagram of the proximity detection circuit according to another embodiment of the present application;

FIG. 7 shows a flowchart of the proximity detection method according to another embodiment of the present application;

FIG. 8 shows a schematic diagram of compensating the baseline data according to another embodiment of the present application;

FIG. 9 shows a block diagram of the proximity detection circuit according to another embodiment of the present application;

FIG. 10 shows a block diagram of the proximity detection circuit according to another embodiment of the present application;

FIG. 11 shows a flowchart of the proximity detection method according to another embodiment of the present application;

FIG. 12 shows a schematic diagram of compensating the proximity threshold according to another embodiment of the present application;

FIG. 13 shows a flowchart of the proximity detection method according to another embodiment of the present application; and

FIG. 14 shows a block diagram of the proximity detection circuit according to another embodiment of the present application.

### DETAILED DESCRIPTION OF THE INVENTION

In order to make the structure and characteristics as well as the effectiveness of the present application to be further understood and recognized, the detailed description of the present application is provided as follows along with embodiments and accompanying figures.

In the specifications and subsequent claims, certain words are used for representing specific devices. A person having ordinary skill in the art should know that hardware manufacturers might use different nouns to call the same device. In the specifications and subsequent claims, the differences in names are not used for distinguishing devices. Instead, the differences in functions are the guidelines for distinguishing. In the whole specifications and subsequent claims, the word “comprising” is an open language and should be explained as “comprising but not limited to”. Besides, the word “couple” includes any direct and indirect electrical connection. Thereby, if the description is that a first device is coupled to a second device, it means that the first device is connected electrically to the second device directly, or the first device is connected electrically to the second device via other device or connecting means indirectly.

Today's proximity sensor applications are often affected by environmental factors, leading to misjudgments. Hence, the present application provides a proximity detection circuit and a proximity detection method with compensation, which may generate a proximity signal indicating whether a human body is proximate, and may further use a reference signal corresponding to environmental factors for compensation, which may be lower the influence by environmental factors. The problem of misjudgment due to the influence of environmental factors, such as the misjudgment of proximity events, may be reduced and thus improving the accuracy of proximity sensing.

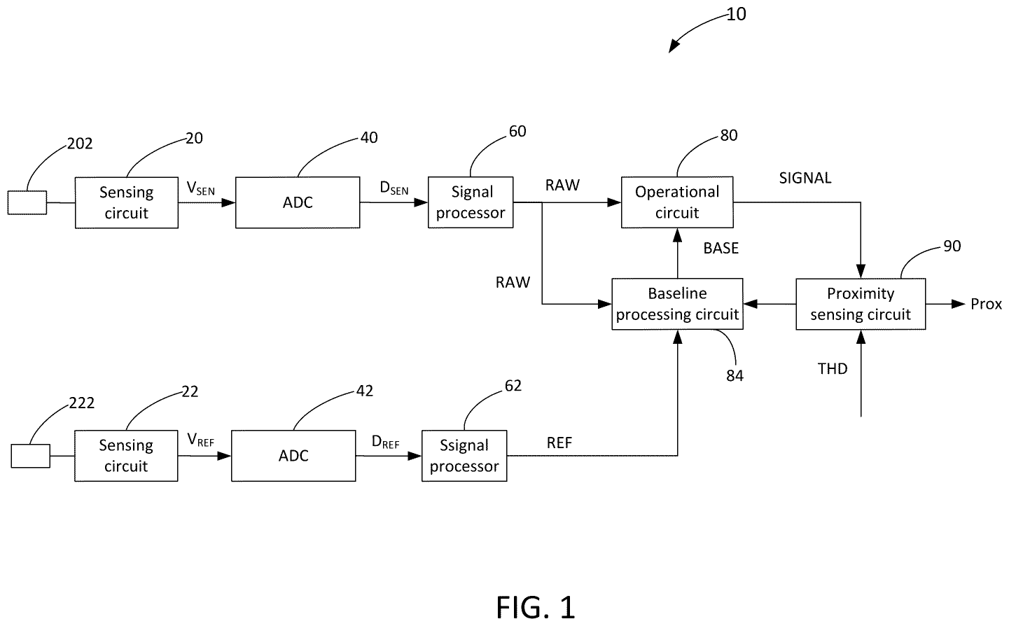

Please refer to FIG. 1, which shows a block diagram of the proximity detection circuit according to an embodiment of the present application. According to the present embody, the proximity detection method may be applied to a proximity detection circuit 10, which may be applied to smartphones, tablet computers, or other consumer electronic devices. The proximity detection circuit 10 comprises a detection circuit, a proximity sensing circuit 90, and a baseline processing circuit 84. The detection circuit according to the present embodiment may include two sensing circuits 20, 22, two analog-to-digital converters (ADC) 40, 42, and two signal processors 60, 62. According to an embodiment of the present application, the sensing circuits 20, 22 are both capacitive sensing circuits. The sensing circuit 20 is coupled to a sensing electrode 202 correspondingly for sensing the sensing electrode 202. The sensing electrode 202 is disposed on one side of an electronic device (not shown in the figure) and close to the user interface surface of the electronic device. The sensing electrode 202 is equivalent to a capacitor. Besides, the sensing circuit 22 is coupled to a reference electrode 222 correspondingly. The reference electrode 222 is disposed on the other side of the electronic device and away from the user interface surface of the electronic device. The equivalence capacitance of the sensing electrode 202 will be influenced and changed by people or objects, for example, human bodies or stylus pens. In addition, it will be changed by environmental factors. The equivalent capacitance of the reference electrode 222 will be influenced and changed by environmental factors, for example, the ambient temperature, humidity, or the temperature of the electronic device, but not by people or objects, for example, human bodies or stylus pens. The sensing circuit 20 may transmit a signal to the sensing electrode 202, which generate an electrical signal, such as a voltage or charge signal related to the equivalent capacitance of the sensing electrode 202, corresponding to the signal. The sensing circuit 20 generates a sensing signal V_{SEN} according to the electrical signal of the sensing electrode 202. The sensing signal V_{SEN} is related to the equivalent capacitance of the sensing electrode 202. The sensing principle of the sensing circuit 22 and the reference electrode 222 is identical to the sensing principle of the sensing circuit 20 and the sensing electrode 202 as described above. Hence, the details will not be repeated. According to a generated reference signal V_{REF}, the capacitance variation of the reference electrode 222 by environmental factors will be deduced, which, in turn, gives the capacitance variation of the sensing electrode 202 by environmental factors. According to an embodiment of the present application, the sensing signal V_{SEN} and the reference signal V_{REF} are analog signals.

Please refer to FIG. 1 again. The analog-to-digital converters 40, 42 are coupled to the sensing circuits 20, 22, respectively, and convert the sensing signal V_{SEN} of the sensing circuit 20 and the reference signal V_{REF} of the sensing circuit 22 to a sensing digital signal D_{SEN} and a reference digital signal D_{REF}. The signal processor 60, 62 are coupled to the analog-to-digital converters 40, 42, respectively, for processing the sensing digital signal D_{SEN} and the reference digital signal D_{REF} and generating detection data RAW and reference data REF, respectively. The values of the detection data RAW and the reference data REF represent the equivalent capacitance of the sensing electrode 202 and the reference electrode 222. The signal processor 60 may be coupled to the proximity sensing circuit 90 and the baseline processing circuit 84 for transmitting the detection data RAW to the proximity sensing circuit 90 and the baseline processing circuit 84. The signal processor 62 is coupled to the baseline processing circuit 84 for transmitting the reference data REF to the baseline processing circuit 84.

According to an embodiment of the present application, the signal processor 60 may receive and average multiple sensing digital signals D_{SEN} and give a value of the detection data RAW. Alternatively, there may be no averaging; a single sensing digital signal D_{SEN} corresponds to a value of the detection data RAW. In addition, the signal processor 60 may filter the sensing digital signal D_{SEN} for filtering out noise. Likewise, the signal processor 60 may receive and average multiple reference digital signals D_{REF} and give a value of the reference data REF. Alternatively, there may be no averaging; a single reference digital signal D_{REF} corresponds to a value of the reference data REF. In addition, the signal processor 60 may filter the reference digital signal D_{REF}. According to the present embodiment, an operational circuit 80 is coupled to the signal processor 60, the baseline processing circuit 84, and the proximity sensing circuit 90. The baseline processing circuit 84 may generate baseline data BASE according to the detection data RAW or according to the detection data RAW and the reference data REF and transmit the baseline data BASE to the operational circuit 80. The operational circuit 80 generates a difference value SIGNAL according to the detection data RAW and the baseline data BASE. The proximity sensing circuit 90 is coupled to the baseline processing circuit 84 and generates a proximity signal Prox according to the corresponding difference value SIGNAL of the detection data RAW and the baseline data BASE and a proximity threshold THD. The proximity signal Prox may represent proximity of human body or object to the electronic device. According to an embodiment of the present embodiment, the value 1 of the proximity signal Prox represents proximity of human body or object to the electronic device. Nonetheless, the present application is not limited to the embodiment. Alternatively, the value 0 of the proximity signal Prox represents proximity of human body or object to the electronic device.

Besides, the baseline processing circuit 84 according to the present embodiment further correct the baseline data BASE according to the reference data REF. Thereby, the operational circuit 80 may further correct the baseline data BASE and the detection data RAW to give the difference value SIGNAL, hence avoiding misjudgment due to environmental factors when the proximity sensing circuit 90 generates the proximity signal Prox according to the difference value SIGNAL and the proximity threshold THD. In the following, the proximity detection method according to the present application will be illustrated by examples.

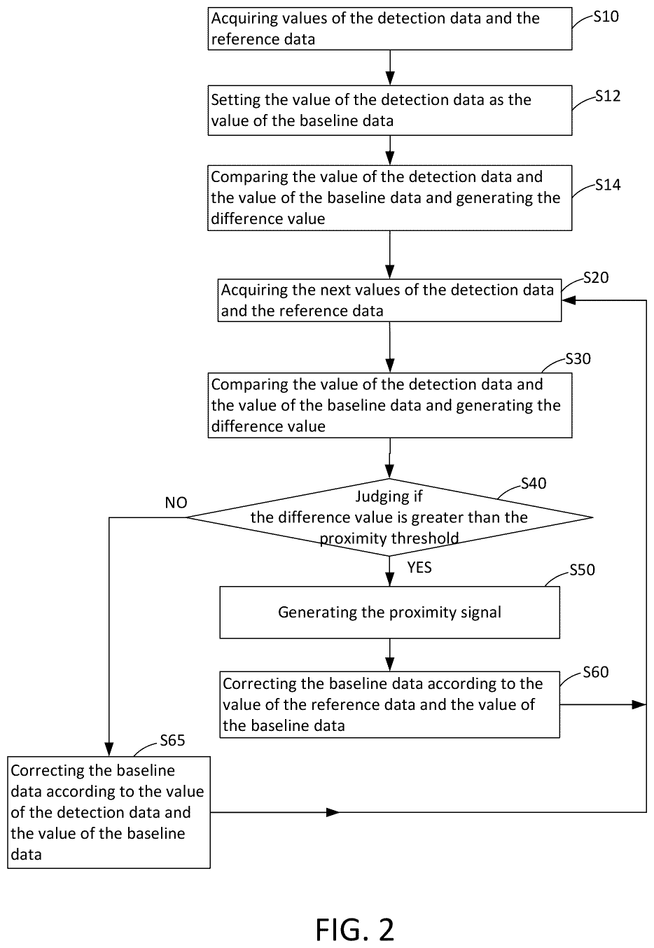

Please refer to FIG. 2, which shows a flowchart of the proximity detection method according to an embodiment of the present application. As shown in the figure, the method comprises steps of:
Step S10: Acquiring values of the detection data and the reference data;
Step S12: Using the value of the detection data as the value of the baseline data;
Step S14: Comparing the value of the detection data with the value of the baseline data to generate the difference value;
Step S20: Acquiring the next values of the detection data and the reference data;
Step S30: Comparing the value of the detection data with the value of the baseline data to generate the difference value;
Step S40: Judging if the difference value is greater than the proximity threshold; and if yes, executing the step S50, otherwise the step S65;
Step S50: Generating the proximity signal;
Step S60: Correcting the baseline data according to the value of the reference data and the value of the baseline data; and
Step S65: Correcting the baseline data according to the value of the detection data and the value of the baseline data.

As shown in FIG. 2, execute the step S10 of the proximity detection method. The proximity detection circuit of the detection circuit generates the detection data RAW and the reference data REF. The baseline processing circuit 84 receives the detection data RAW and the reference data REF. In particular, the detection circuit detects the reference electrode 222 and generates the corresponding reference data REF. In addition, the baseline processing circuit 84 is used for generating the baseline data BASE for the operational circuit 80 to generate the difference value SIGNAL. Next, execute the step S12. The baseline processing circuit 84 uses the value of the detection data RAW acquired in the step S10 as the value of the baseline BASE. According to an embodiment of the present application, the initial value RAW[0] of the detection data RAW is used as the initial value BASE[0] of the baseline data BASE, BASE[n]=RAW[n], n=0. Next, execute the step S14. The operational circuit 80 compares the value of the detection data RAW with the value of the baseline data BASE to generate the difference value SIGNAL correspondingly. At this time, since the value of the detection data RAW is equal to the value of the baseline data BASE, the difference value SIGNAL is 0. In other words, the difference value SIGNAL acquired at start by the proximity detection circuit 10 will not be greater than the threshold THD. Thereby, execute the step S20.

Please refer to FIG. 2. Execute the step S20. The proximity detection circuit 10 performs the next sensing. In other words, the detection circuit provides the next values of the detection data RAW and the reference data REF. Then, execute the step S30. The operational circuit 80 compares the value of the detection data RAW with the value of the baseline data BASE to generate the difference value SIGNAL. According to an embodiment of the present application, the detection circuit provides the current values (Raw[n], Ref[n]) of the detection data RAW and the reference data REF. The operational circuit 80 compares the current value (the nth value) of the detection data RAW with the previous value (the (n−1)th value) of the baseline data BASE to generate the difference value SIGNAL, which may be expressed as SIGNAL=Raw[n]−Base[n−1], where n is a positive integer and greater or equal to 1.

Please refer to FIG. 2 again. The proximity sensing circuit 90 executes the step S40 for judging if the difference value SIGNAL is greater than the proximity threshold THD. When the difference value SIGNAL is greater than the threshold THD, it means an object or a human body is proximate to the electronic device. Since the capacitance is increased significantly, the difference value SIGNAL will be exceeded the proximity threshold THD. Then the proximity sensing circuit 90 executes the step S50 for generating the proximity signal Prox. The proximity threshold THD is set according to design requirements. According to the above description, the proximity sensing circuit 90 generates the proximity signal Prox according to the detection data RAW, the baseline data BASE, and the proximity threshold THD. According to an embodiment of the present application, the operational circuit 80 may be integrated in the proximity sensing circuit 90.

According to an embodiment of the present application, the baseline processing circuit 84 corrects the baseline data BASE according to the reference data REF. Namely, the baseline processing circuit 84 generates the baseline data BASE according to the detection data RAW and the reference data REF. When the baseline processing circuit 84 acquires the first value of the detection data RAW and the reference data REF (Raw[n], Base[n], n=0) in the step S10, the first value of the detection data RAW is used as the initial value (Raw[n]=Base[n], n=0) of the baseline data BASE. The operational circuit 80 compares the first value of the detection data RAW with the initial value of the baseline data BASE to generate the difference value SIGNAL of 0, which is smaller than the proximity threshold THD. The baseline processing circuit 84 executes the step S20 to acquire the second values of the detection data RAW and the reference data REF.

Next, the operational circuit 80 acquires the second value of the detection data RAW in the step S20 and compares the second value of the detection data RAW with the first value of the baseline data BASE to generate the second difference value SIGNAL. In the step S40, the operational circuit 80 judges if the difference value SIGNAL is greater than the proximity threshold THD for judging proximity of human body or object. If the second difference value SIGNAL between the second value of the detection data RAW and the first value of the baseline data BASE is greater than the proximity threshold THD, the proximity sensing circuit 90 will generate the proximity signal Prox. Like the above description, if the difference value SIGNAL between the second value of the detection data RAW and the first value of the baseline data BASE is smaller than the threshold value THD, the proximity sensing circuit 90 drives the baseline processing circuit 84 to generate the second value (Base[n], n=1) of the baseline data BASE according to the second value (Raw[n], n=1) of the detection data RAW and the first value (Base[n−1], n=1) of the baseline data BASE in the step S65. The baseline processing circuit 84 generates the current value (the second value) of the baseline data BASE according to the current value (the second value) of the detection data RAW and the previous value (the first value) of the baseline data BASE. It may be expressed as Base[n]=C*Raw[n]+(1−C)*Base[n−1], where C is a parameter that is positive and smaller than 1 and may be set according to requirements. The above n is a positive integer and greater or equal to 1. Next, the operational circuit 80 acquires the third value of the detection data RAW in the step S20 and compares the third value (Raw[n+1], n=2) of the detection data RAW with the second value (Base[n], n=2) of the baseline data BASE to generate the third difference value SIGNAL. The operational circuit 80 judges if the difference value SIGNAL is greater than the proximity threshold THD for judging proximity of human body or object. The difference value SIGNAL generated by the operational circuit 80 may be expressed as SIGNAL=Raw[n+1]-Base[n], n=2.

After the proximity circuit 90 generates the proximity signal Prox, execute the step S60. When the proximity sensing circuit 90 judges the occurrence of a proximity event, it controls the baseline processing circuit 84 to correct the baseline data BASE according to the value of the baseline data BASE and the value of the reference data REF. In other words, the value of the baseline data BASE is corrected according to the corresponding reference data REF of environmental factors for avoiding influence of environmental factors on the judgment. Next, execute the step S20 to acquire the next value of the detection data RAW and the reference data REF. Then the operational circuit 80 may compare the next value of the detection data RAW with the corrected baseline data to generate the difference value SIGNAL. Then proximity sensing circuit 90 judges if the corresponding difference value SIGNAL of the corrected baseline data BASE is greater than the proximity threshold THD until the object or the human body is judged away from the electronic device. Then execute the step S65 for correcting the value of the baseline data BASE according to the value of the detection data RAW and the value of the baseline data BASE.

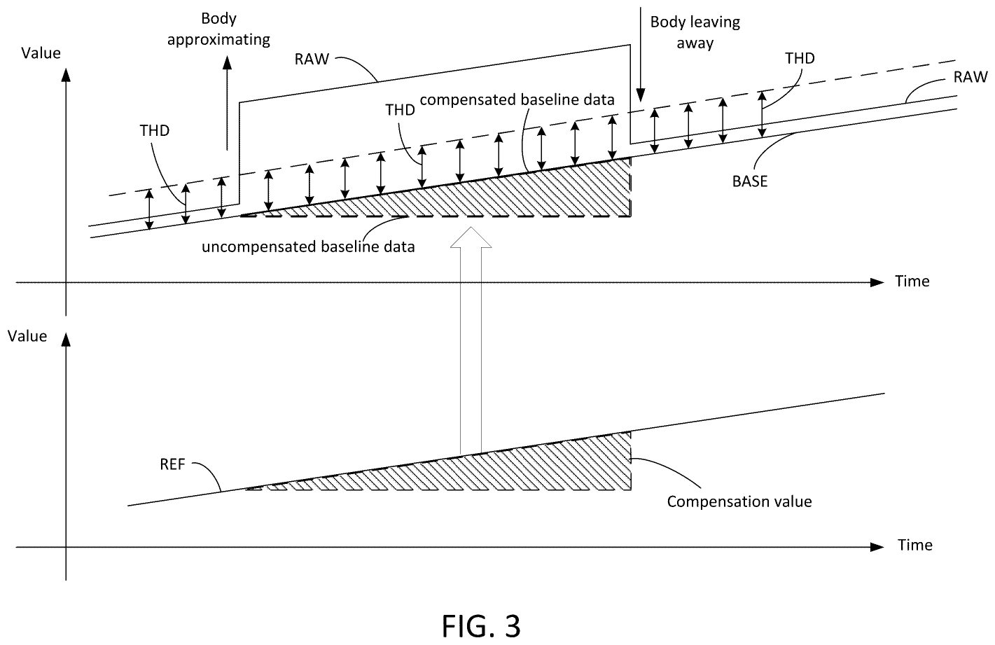

According to an embodiment of the present application, the value of the reference data REF changes with variation of environmental factors. When the difference value SIGNAL is judged to be greater than the proximity threshold THD and generating the proximity signal Prox, execute the step S60. The proximity sensing circuit 90 drives the baseline processing circuit 84 corrects the baseline data BASE according to the current value (Ref[n]) and the previous value (Ref[n−1]) of the reference data REF and the previous value (Base[n−1]) of the baseline data BASE and acquires the current value (Base[n]) of the baseline data BASE, which may be expressed as Base[n]=Base[n−1]+G*(Ref[n]−Ref[n−1]), where G is set according to the characteristic (for example, ratio) of the sensing electrode 202 and the reference electrode 222; and n is a positive integer greater than or equal to 1. Thereby, when an object or a human body is proximate to an electronic device, the values of the baseline data BASE may be compensated continuously. Consequently, the values of the baseline data BASE, like the values of the detection data RAW, may change with variation of the environmental factors. Then, when the proximity status is changed, the difference value SIGNAL generated by comparing the compensated baseline data BASE with the detection data RAW will not be influenced by the environmental factors, as shown in FIG. 3.

If the proximity sensing circuit 90 judges that the difference value SIGNAL between the third value (Raw[n+1]) of the detection data RAW and the second value (Base[n]) of the baseline data BASE is greater than the proximity threshold THD, it will generate the proximity signal Prox for representing proximity of human body or object. In addition, the proximity detection circuit 10 will continue to execute the step S60 for correcting the baseline data BASE continuously. The steps of the proximity detection method will be executed continuously for judging proximity events continuously.

To sum up, the baseline processing circuit 84 corrects the baseline data BASE according to the value of the baseline data BASE and the value of the reference data REF. Then the proximity sensing circuit 90 may judge if the proximity signal Prox should be generated according to the proximity detection data RAW, the proximity threshold THD, and the above corrected baseline data BASE. By avoiding the influence of environmental factors such as temperature or humidity, misjudgments (for example, proximity events) may be prevented and hence improving the accuracy of proximity sensing.

As shown in FIG. 3, when it is judged to generate the proximity signal Prox, according to an embodiment of the present application, correct the baseline data BASE according to the current value (Ref[n]) and the previous value (Ref[n−1]) of the reference data REF and the previous value (Base[n−1]) of the baseline data BASE and giving the current value (Base[n]) of the baseline data BASE. In other words, the values of the baseline data BASE may change as the corresponding reference data REF of environmental factors vary. For example, temperature or humidity variation may lead to increase of capacitance. Namely, the value of the detection data RAW will increase. Then, based on the corresponding compensation value of the reference data REF, the baseline value will be changed from an uncompensated baseline value to a compensated baseline value. When the object or the human body is away from the electronic device, the value of the detection data RAW decreases. The difference value between the current value of the detection data RAW and the current value of the compensated baseline data BASE is smaller than the proximity threshold THD. Then the object or the human body is judged to be away from the electronic device. Thereby, misjudgments, for example, proximity events, may be reduced.

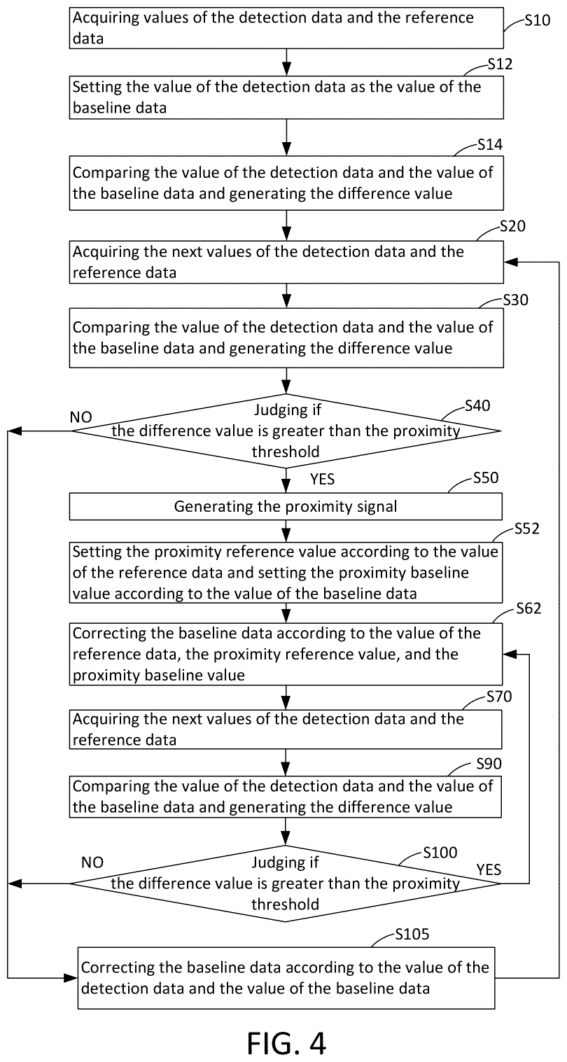

Please refer to FIG. 4, which shows a flowchart of the proximity detection method according to another embodiment of the present application. The difference between FIG. 2 and FIG. 4 is that, after the step S50 in FIG. 4, the values of the reference data REF and the baseline data BASE are further set for correcting the baseline data BASE, as described as follows.

As shown in the figure, the proximity detection method comprises steps of:
Step S10: Acquiring values of the detection data and the reference data;
Step S12: Setting the value of the detection data as the value of the baseline data;
Step S14: Comparing the value of the detection data with the value of the baseline data to generate the difference value;
Step S20: Acquiring the next values of the detection data and the reference data;
Step S30: Comparing the value of the detection data with the value of the baseline data to generate the difference value;
Step S40: Judging if the difference value is greater than the proximity threshold; and if yes, executing the step S50, otherwise the step S105;
Step S50: Generating the proximity signal;
Step S52: Setting the proximity reference value according to the value of the reference data and Setting the proximity baseline value according to the value of the baseline data;
Step S62: Correcting the baseline data according to the value of the reference data, the proximity reference value, and the proximity baseline value;
Step S70: Acquiring the next values of the detection data and the reference data;
Step S90: Comparing the value of the detection data with the value of the baseline data to generate the difference value;
Step S100: Judging if the difference value is greater than the proximity threshold; and if yes, executing the step S62, otherwise the step S105; and
Step S105: Correcting the baseline data according to the value of the detection data and the value of the baseline data.

The steps S10 to S50 are identical to the above embodiment. Hence, the details will not be repeated. The steps S70 to S100 are identical to the steps S20 to S40; the step S105 is identical to the step S65 of the previous embodiment. Hence, the details will not be repeated. Please refer to FIG. 1 and FIG. 4. When the proximity sensing circuit 90 generates the proximity signal Prox, namely, when the proximity sensing circuit 90 judges the occurrence of proximity events, it controls the baseline processing circuit 84 to further set a proximity reference value and a proximity baseline value according to the value of the reference data REF and the value of the baseline data BASE, respectively, in the step S52. Next, in the step S62, the baseline processing circuit 84 corrects the baseline data BASE according to the value of the reference data REF acquired in the step S20 and the proximity reference value and the proximity baseline value set in the step S52. Thereby, the difference value SIGNAL acquired in the step S90 by comparing the value of the detection data with the value of the baseline data corresponds to the corrected baseline data BASE, namely, the value of the reference data REF acquired in the step S20 and the proximity reference value and the proximity baseline value set in the step S52. In the steps S40 and S105, when the proximity sensing circuit 90 judges that the difference value SIGNAL is smaller than the proximity threshold THD, it further drives the baseline processing circuit 84 to correct the baseline data BASE according to the value of the detection data RAW and the value of the baseline data BASE.

According to another embodiment of the present application, when the proximity sensing circuit 90 judges the occurrence of proximity event, in the step S52, it controls the baseline processing circuit 84 sets the proximity reference value prox_ref0 and the proximity baseline value prox_base0 according to the previous value (Ref[n−1]) of the reference data REF and the previous value (Base[n−1]) of the baseline data BASE, respectively, expressed by prox_ref0=Ref[n−1] and prox_base0=Base[n−1], where n is a positive integer greater than or equal to 1. Next, in the step S62, the baseline processing circuit 84 corrects the baseline data BASE according to the proximity baseline value (prox_base0), the current value (Ref[n]) of the reference data REF, and the proximity reference value (prox_ref0) and gives the current value (Base[n]) of the baseline data BASE, which may be expressed by Base[n]=prox_base0+G*(Ref[n]−prox_ref0). G is set according to the characteristic (for example, ratio) of the sensing electrode 202 and the reference electrode 222; and n is a positive integer greater than or equal to 1.

According to another embodiment of the present application, the operational circuit 80 acquires the next value (the third value, Raw[n+1]) of the detection data RAW in the step S70. The baseline processing circuit 84 acquires the next value (the third value, Ref[n+1]) of the reference data REF in the step S70. In addition, in the step S52, the proximity reference value prox_ref0 is set and locked. The operational circuit 80 compares the third value (Raw[n+1]) of the detection data RAW with the second value (Base[n]) of the baseline data BASE to generate the difference value SIGNAL. In the step S90, if the difference value SIGNAL is greater than the proximity threshold THD, the proximity sensing circuit 90 judges the occurrence of proximity event and generates the proximity signal Prox. Thereby, in the step S100, the difference value SIGNAL generated by the operational circuit 80 corresponds to the proximity baseline value (prox_base0), the current value (Ref[n]) of the reference data REF, and the proximity reference value (prox_ref0). In other words, the proximity sensing circuit 90 generates the proximity signal Prox according to the detection data RAW, the proximity baseline value (prox_base0), the current value (Ref[n]) of the reference data REF, and the proximity reference value (prox_ref0). In the above, n is a positive integer greater than or equal to 1.

According to another embodiment of the present application, after judging the occurrence of a proximity event in the step S100, in the step S62, the proximity sensing circuit 90 controls the baseline processing circuit 84 to correct the baseline data BASE according to the proximity baseline value (prox_base0), the current value (the third value, Ref[n+1]) of the reference data REF, and the proximity reference value (prox_ref0) and giving the current value (the third value, Base[n+1]) of the baseline data BASE. Next, in the step S70, acquire the next value (the fourth value, Raw[n+2]) of the detection data RAW. Then the operational circuit 80 acquires the difference value SIGNAL according to the fourth value (Raw[n+2]) of the detection data RAW and the current value (the third value, Base[n+1]) of the baseline data BASE. Since the difference value SIGNAL is greater than the proximity threshold THD, the proximity sensing circuit 90 judges the occurrence of proximity event and generates the proximity signal Prox. Similar to the above description, if no proximity event occurs in the step S100, the proximity sensing circuit 90 controls the baseline processing circuit 84 to correct the baseline data BASE according to the current value (the third value, Raw[n+1]) of the detection data RAW and the previous value (the second value, Base[n]) of the baseline data BASE and generating the current value (the third value, Base[n+1]) of the baseline data BASE. Next, return to the step S20. The operational circuit 80 receives the next value (the fourth value, Raw[n+2]) of the detection data RAW and acquires the difference value SIGNAL according to the next value (the fourth value, Raw[n+2]) of the detection data RAW and the current value (the third value, Base[n+1]) of the baseline data. Since the difference value SIGNAL is greater than the proximity threshold THD, the proximity sensing circuit 90 judges the occurrence of proximity event and generates the proximity signal Prox. The above n is a positive integer greater than or equal to 1.

According to another embodiment of the present application, in the step S40, if the difference value SIGNAL is smaller than the proximity threshold THD and the proximity sensing circuit 90 judges no proximity event, the proximity sensing circuit 90 controls the baseline processing circuit 84 to correct the baseline data BASE according to the current value (the second value, Raw[n]) of the detection data RAW and the previous value (Base[n−1]) of the baseline data BASE and giving the current value (Base[n]) of the baseline data BASE. The above n is a positive integer greater than or equal to 1.

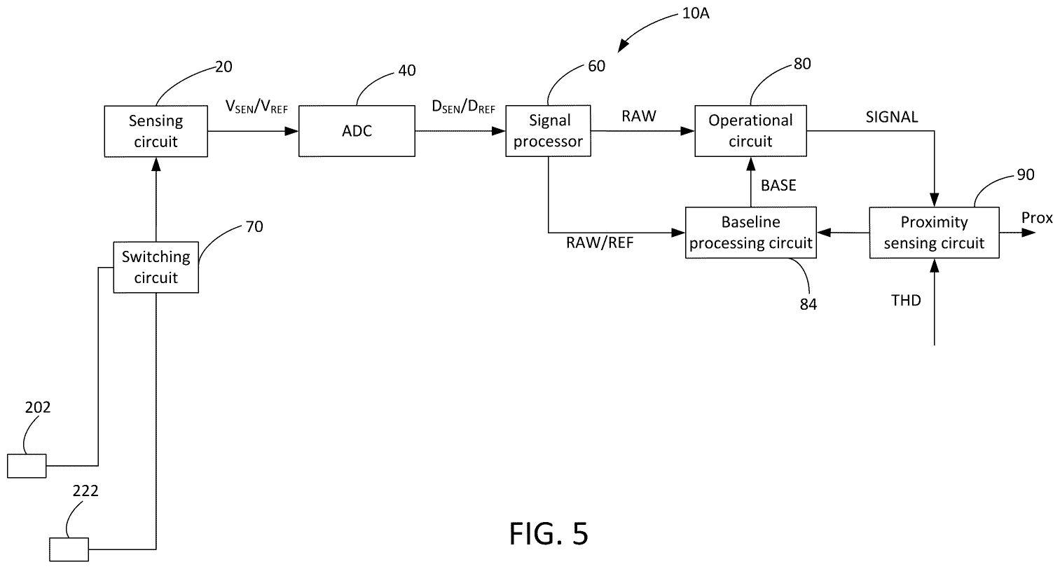

Please refer to FIG. 5, which shows a block diagram of the proximity detection circuit according to another embodiment of the present application. The difference between FIG. 1 and FIG. 5 is that the sensing electrode 202 and the reference electrode 222 of the proximity detection circuit 10 in FIG. 1 are coupled to the sensing circuits 20, 22, respectively. Thereby, the signal processors 60, 62 output the detection data RAW and the reference data REF, respectively. The proximity detection circuit 10A in FIG. 5 further comprises a switching circuit 70; the sensing electrode 202 and the reference electrode 222 are coupled to the sensing circuit 20 via the switching circuit 70. Thereby, the sensing circuit 20 generates the sensing signal V_{SEN} and the reference signal V_{REF}. The analog-to-digital converter 40 generates the corresponding sensing digital signal D_{SEN} and the reference digital signal D_{REF} according to the sensing signal V_{SEN} and the reference signal V_{REF}. The signal processor 60 generates the corresponding detection data RAW and the reference data REF according to the sensing digital signal D_{SEN} and the reference digital signal D_{REF}. According to the present embodiment, the sensing circuit 20, the analog-to-digital converter 40, and the signal processor 60 may be shared.

According to another embodiment, a timing control signal (not shown in the figure) is used to control the switching circuit 70, so that the sensing circuit 20 may switch to couple to the sensing electrode 202 or the reference electrode 222 and be driven to generate the sensing signal V_{SEN} and the reference signal V_{REF} at different timing. Thereby, the analog-to-digital converter 40 may generate the sensing digital signal D_{SEN} and the reference digital signal D_{REF} at different timing correspondingly and the signal processor 60 may generate the values of the detection data RAW and the reference data REF at different timing. Then the operational circuit 80 may acquire the value of the detection data RAW; the baseline processing circuit 84 may acquire the value of the detection data RAW and the value of the reference data REF. Accordingly, the proximity detection circuit 10A may execute the proximity detection method shown in FIG. 2 or FIG. 4.

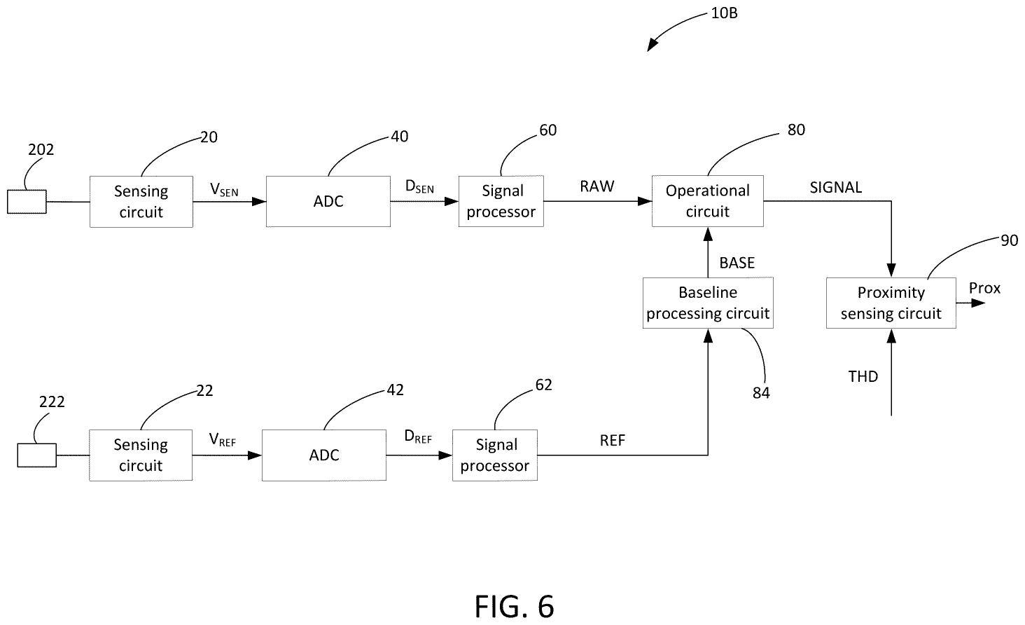

Please refer to FIG. 6, which shows a block diagram of the proximity detection circuit according to another embodiment of the present application. The difference between FIG. 1 and FIG. 6 is that the signal processor 60 of the proximity detection circuit 10 in FIG. 1 generates the detection data RAW to the operational circuit 80 and the baseline processing circuit 84. Then the baseline processing circuit 84 may generate the baseline data BASE according to the detection data RAW and the reference data REF. Contrarily, the signal processor 60 of the proximity detection circuit 10B in FIG. 6 generates the detection data RAW to the operational circuit 80. Then the baseline processing circuit 84 may generate the baseline data BASE according to the reference data REF. Since the operational circuit 80 in FIG. 6 generates the difference value SIGNAL according to the detection data RAW and the baseline data BASE, the baseline data BASE will not be influenced by the detection data RAW, meaning generating the difference value SIGNAL according to the detection data RAW and the reference data REF. The rest connections and operating principles are identical to the embodiment in FIG. 1. Hence, the details will not be repeated.

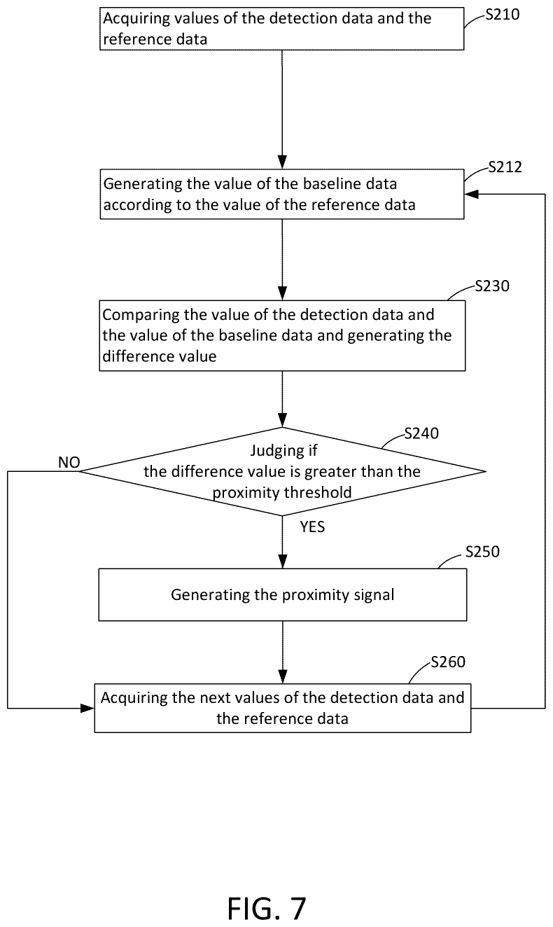

Please refer to FIG. 7, which shows a flowchart of the proximity detection method according to another embodiment of the present application. The difference between FIG. 2 and FIG. 7 is that in FIG. 2, after judging that the difference value SIGNAL is greater than the proximity threshold THD and generating the proximity signal Prox, correct the baseline data BASE according to the value of the baseline data BASE and the value of the reference data REF, and after judging that the difference value SIGNAL is smaller than the proximity threshold THD, correct the baseline data BASE according to the value of the baseline data BASE and the value of the detection data RAW. Contrarily, in FIG. 7, after judging that the difference value SIGNAL is greater than the proximity threshold THD and generating the proximity signal Prox and after judging that the difference value SIGNAL is smaller than the proximity threshold THD, correct the baseline data BASE according to the reference data REF. The details will be described as follows.

As shown in the figure, the method comprises steps of:
Step S210: Acquiring values of the detection data and the reference data;
Step S212: Generating the value of the baseline data according to the value of the reference data;
Step S230: Comparing the value of the detection data with the value of the baseline data to generate the difference value;
Step S240: Judging if the difference value is greater than the proximity threshold; and if yes, executing the step S250, otherwise the step S260;
Step S250: Generating the proximity signal; and
Step S260: Acquiring the next values of the detection data and the reference data.

The step S210 and the steps S230 to S250 are identical to the step S10 and the steps S30 to S50. Hence, they will not be described again. The baseline processing circuit 84 executes the step S212 for generating the corresponding baseline data BASE according to the value of the reference data REF acquired previously. The baseline data BASE is used for generating the difference value SIGNAL in the step S230. After the proximity sensing circuit 90 judging that the difference value SIGNAL is greater than the threshold THD in the step S240 and generating the proximity signal Prox, the step S260 is executed. After the proximity sensing circuit 90 judging that the difference value SIGNAL is smaller than the threshold THD in the step S240, the step S260 is executed as well. The baseline processing circuit 84 acquires the reference data REF in the step S260. The operational circuit 80 also acquires the detection data RAW in the step S260. Then, in the step S212, the baseline processing circuit 84 corrects the baseline data BASE according to the value of the reference data REF. Next, the operational circuit 80 generates the difference value SIGNAL according to the corrected baseline data BASE and the detection data RAW for further judging if the difference value SIGNAL is greater than the proximity threshold THD. In other words, no matter whether the difference value SIGNAL is greater than the proximity threshold THD, the baseline processing circuit 84 corrects the baseline data BASE according to the value of the reference data REF.

According to another embodiment of the present application, no matter whether the difference value SIGNAL is greater than the proximity threshold THD, namely, no matter whether a proximity event occurs, the baseline processing circuit 84 generates the current value (Base[n]) of the baseline data BASE according to the value of the reference data REF. The value of the reference data REF may be calculated using the corresponding equation according to the requirement. According to another embodiment of the present application, the baseline processing circuit 84 generates the current value (Base[n]) of the baseline data BASE according to the current value (Ref[n]) of the reference data REF and an offset value. The equation may be expressed as Base[n]=G*Ref[n]+offset. G is set according to the characteristic (for example, ratio) of the sensing electrode 202 and the reference electrode 222; and n is a positive integer greater than or equal to 0. The offset value is set according to the material of the reference electrode 222 and process parameters.

According to another embodiment of the present application, since the baseline data BASE generated by the detection data RAW and the reference data REF at start might lead to the difference value of 0, the details will not be repeated. The baseline processing circuit generates the current value (the second value, Base[n]) of the baseline data BASE according to the current value (the second value, Ref[n]) of the reference data REF. In the step S230, the operational circuit 80 compares the current value (the second value, Raw[n]) of the detection data RAW with the current value (the second value, Base[n]) of the baseline data BASE and generates the difference value SIIGNAL. In the step S240, the proximity sensing circuit 90 judges that the difference value SIGNAL is smaller than the proximity threshold THD and hence judging no proximity event. Next, in the step S260, control the baseline processing circuit 84 to give the next value (the third value, Ref[n+1]) of the reference data REF. The baseline processing circuit 84 generates the current value (the third value, Base[n+1]) of the baseline data BASE according to the current value (the third value, Ref[n+1]) of the reference data REF. Thereby, the operational circuit 80 may compare the current value (the third value, Raw[n+1]) of the detection data RAW with the current value (the third value, Base[n+1]) of the baseline data BASE and generates the difference value SIGNAL. In the step S240, the proximity sensing circuit 90 judges that the difference value SIGNAL is greater than the proximity threshold THD and hence judging the occurrence of proximity event and generating the proximity signal Prox. The above n is a positive integer greater than or equal to 1.

According to another embodiment of the present application, since the baseline data BASE generated by the detection data RAW and the reference data REF at start might lead to the difference value of 0, the details will not be repeated. The baseline processing circuit generates the current value (the second value, Base[n]) of the baseline data BASE according to the current value (the second value, Ref[n]) of the reference data REF. In the step S230, the operational circuit 80 compares the current value (the second value, Raw[n]) of the detection data RAW with the current value (the second value, Base[n]) of the baseline data BASE to generate the difference value SIIGNAL. In the step S240, the proximity sensing circuit 90 judges that the difference value SIGNAL is greater than the proximity threshold THD and hence judging the occurrence of proximity event and generating the proximity signal Prox. Next, in the step S260, control the baseline processing circuit 84 to give the next value (the third value, Ref[n+1]) of the reference data REF. The baseline processing circuit 84 generates the current value (the third value, Base[n+1]) of the baseline data BASE according to the current value (the third value, Ref[n+1]) of the reference data REF. Thereby, the operational circuit 80 may compare the current value (the third value, Raw[n+1]) of the detection data RAW with the current value (the third value, Base[n+1]) of the baseline data BASE to generate the difference value SIGNAL. In the step S240, the proximity sensing circuit 90 judges that the difference value SIGNAL is greater than the proximity threshold THD and hence judging the occurrence of proximity event and generating the proximity signal Prox. The above n is a positive integer greater than or equal to 1.

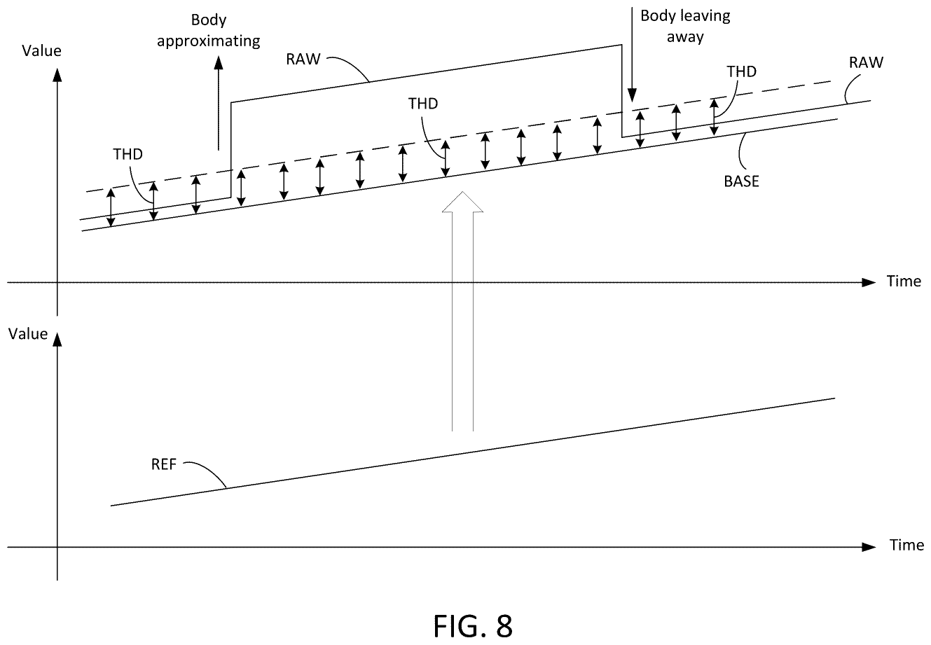

As shown in FIG. 8, since the baseline processing circuit 84 generates the corresponding value of the baseline data BASE only according to the value of the reference data REF corresponding to the environmental factors, the corresponding line of the baseline data BASE is equivalent to the corresponding line of the reference data REF. Thereby, the corresponding curve of the baseline data BASE according to the present embodiment does not appear the uncompensated baseline value shown in FIG. 3.

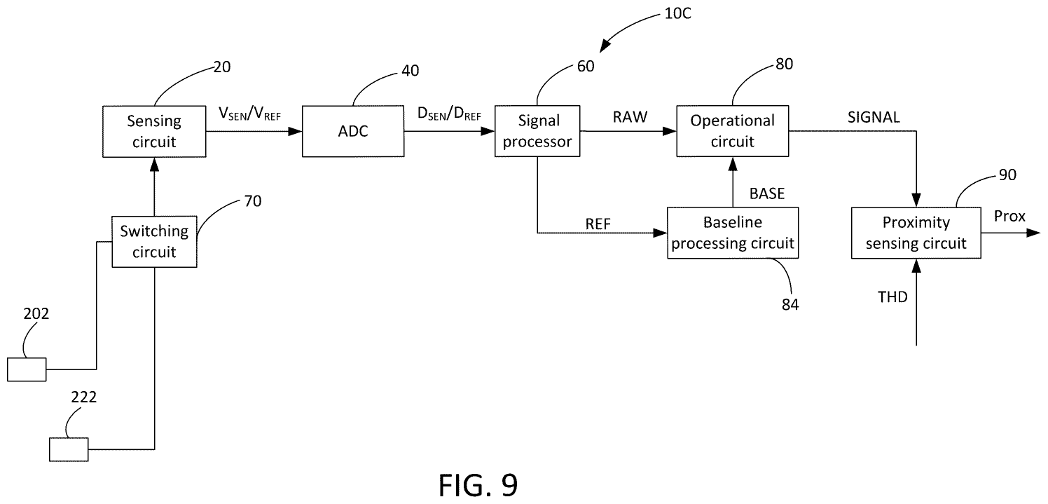

Please refer to FIG. 9, which shows a block diagram of the proximity detection circuit according to another embodiment of the present application. The difference between FIG. 6 and FIG. 9 is that the proximity detection circuit 10C in FIG. 9 further comprises a switching circuit 70; the sensing electrode 202 and the reference electrode 222 are coupled to the sensing circuit 20 via the switching circuit 70. Thereby, the sensing circuit 20 generates the sensing signal V_{SEN} and the reference signal V_{REF} by time division. The analog-to-digital converter 40 generates the corresponding sensing digital signal D_{SEN} and the reference digital signal D_{REF} by time division. The signal processor 60 generates the corresponding detection data RAW and the reference data REF by time division. Thereby, the baseline processing circuit 84 may generate the corresponding value of the baseline data BASE according to the value of the reference data REF. The rest connections and operating principles are identical to the proximity detection circuit 10B in FIG. 6. Hence, the details will not be repeated.

According to the above embodiments, the operational circuit 80 and the baseline processing circuit 84 may be further integrated in the proximity sensing circuit 90. The circuit schemes such as SOC or FPGA may be used to implement the proximity detection circuits 10, 10A, 10B, 10C and adjusted according to requirements.

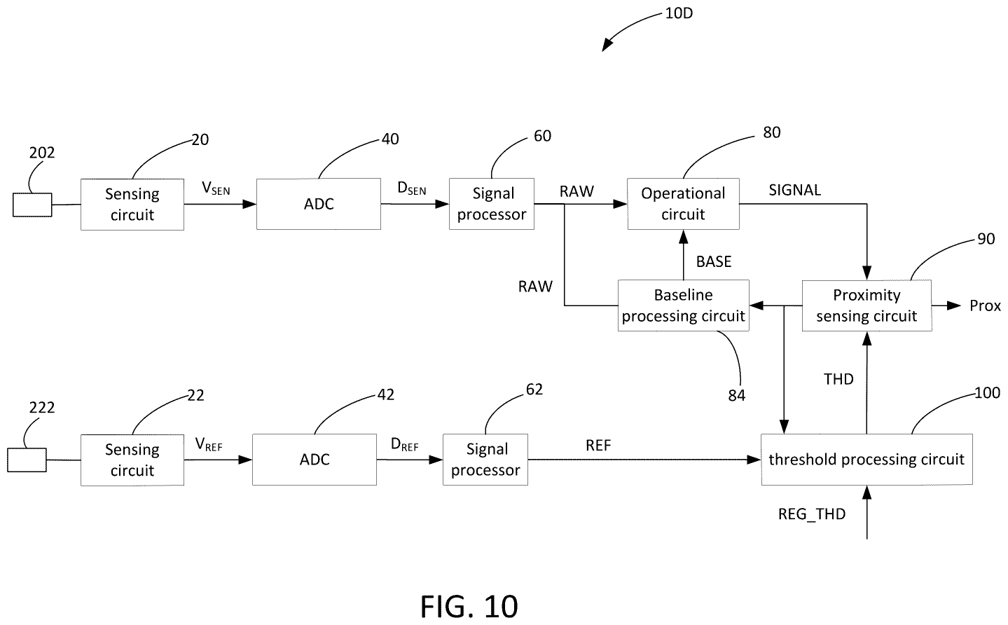

Please refer to FIG. 10, which shows a block diagram of the proximity detection circuit according to another embodiment of the present application. The difference between FIG. 1 and FIG. 10 is that in FIG. 1, the signal processor 62 generates the reference data REF to the baseline processing circuit 84 for generating the baseline data BASE, while in FIG. 10, the proximity detection circuit 10D further comprises a threshold processing circuit 84 for generating the proximity threshold THD according to a preset value REG_THD, and the signal processor 62 generates the reference data REF to the threshold processing circuit 100 for correcting the proximity threshold THD. The rest connections and operating principles are identical to the proximity detection circuit 10 in FIG. 1. Hence, the details will not be repeated. The proximity detection method executed by the proximity detection circuit 10D is described as follows.

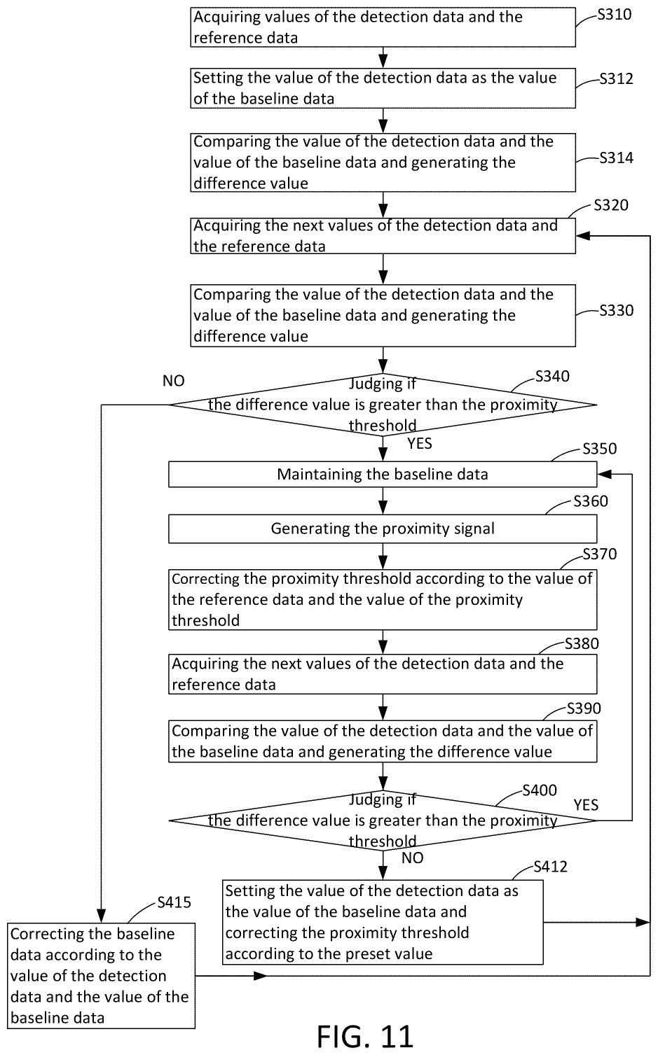

Please refer to FIG. 11, which shows a flowchart of the proximity detection method according to another embodiment of the present application. As shown in the figure, the method comprises steps of:
Step S310: Acquiring values of the detection data and the reference data;
Step S312: Setting the value of the detection data as the value of the baseline data;
Step S314: Comparing the value of the detection data with the value of the baseline data to generate the difference value;
Step S320: Acquiring the next values of the detection data and the reference data;
Step S330: Comparing the value of the detection data and the value of the baseline data and generating the difference value;
Step S340: Judging if the difference value is greater than the proximity threshold; and if yes, executing the step S350, otherwise the step S415;
Step S350: Maintaining the baseline data;
Step S360: Generating the proximity signal;
Step S370: Correcting the proximity threshold according to the value of the reference data and the value of the proximity threshold;
Step S380: Acquiring the next values of the detection data and the reference data;
Step S390: Comparing the value of the detection data with the value of the baseline data to generate the difference value;
Step S400: Judging if the difference value is greater than the proximity threshold; and if yes, executing the step S350, otherwise the step S412;
Step S412: Setting the value of the detection data as the value of the baseline data and correcting the proximity threshold according to the preset value; and
Step S415: Correcting the baseline data according to the value of the detection data and the value of the baseline data.

The steps S310 to S340 and the step S340 are identical to the steps S10 to S40 and the step S50. Hence, the details will not be repeated. The steps S380 to S400 are identical to the steps S320 to S340, Hence, the details will not be repeated. After the proximity sensing circuit 90 judges that the difference value SIGNAL is greater than the proximity threshold THD, execute the step S350 first to drive the baseline processing circuit 90 to maintain the value of the baseline data BASE. In the step S360, after generating the proximity signal Prox, the threshold processing circuit 100 corrects the proximity threshold THD according to the value of the reference data REF and the value of the proximity threshold THD. Then, in the step S380, acquire the next values of the detection data RAW and the reference data REF. Thereby, the baseline data BASE maintained in the step S350, it may be continued to be adopted in the step S390 for generating the difference value SIGNAL.

In addition, in the step S340, the proximity sensing circuit 90 judges that if the difference value SIGNAL is smaller than the proximity threshold THD, the baseline processing circuit 84 is driven to execute the step S415. In the step S400, when the proximity sensing circuit 90 judges that the difference value SIGNAL is smaller than the proximity threshold THD, it drives the baseline processing circuit 84 to use the value of the detection data RAW as the value of the baseline data BASE and corrects the proximity threshold THD according to the preset value REG_THD of the proximity threshold THD.

According to another embodiment of the present application, in the step S340, the proximity sensing circuit 90 judges that the difference value SIGNAL is greater than the proximity threshold and then uses the previous value (Base[n−1]) of the baseline data BASE as the current value (Base[n]) of the baseline data, in other words, maintaining the baseline data BASE and expressed as Base[n]=Base[n−1]. The above n is an integer greater than or equal to 1. Next, the threshold processing circuit 100 performs the step S370 for correcting the proximity threshold THD according to the previous value (THD[n−1]) of the proximity threshold and the current value Ref[n] and the previous value Ref[n−1] of the reference data REF and generating the current value (THD[n]) of the proximity threshold, which may be expressed as THD[n]=THD[n−1]+G*(Ref[n]−Ref[n−1]), where G is set according to the characteristic (for example, ratio) of the sensing electrode 202 and the reference electrode 222; and n is a positive integer greater than or equal to 1.

According to another embodiment of the present application, the difference value SIGNAL between the first values of the detection data RAW and the baseline data BASE is 0. Hence, the details will not be described. After the proximity sensing circuit 90 judges that the difference value SIGNAL between the nth value (Raw[n]) of the detection data RAW and the (n−1)th value (Base[n−1]) of the baseline data is greater than the (n−1)th value (THD[n−1]) of the proximity threshold THD, the step S350 is first executed for driving the baseline processing circuit 84 to maintain the (n−1)th value Base[n−1] of the baseline data BASE as the nth value Base[n] (namely, Base[n]=Base[n−1]). In addition, after generating the proximity signal Prox in the step S360, the threshold processing circuit 100 corrects the proximity threshold THD according to the nth value (Ref[n]) and the (n−1)th value (Ref[n−1]) of the reference data REF and the (n−1)th value (THD[n−1]) of the proximity threshold THD and generates the nth value (THD[n]) of the proximity threshold THD. Next, in the step S380, acquire the next values (Raw[n+1], Ref[n+1]) of the detection data RAW and the reference data REF. Thereby, the value (Base[n]) of the baseline data BASE maintained in the step S350, it may be continued to be adopted in the subsequent step S390 for generating the difference value SIGNAL. In the step S400, the difference value SIGNAL is judged to be greater than the nth value (THD[n]) of the proximity threshold THD, return to the step S350. The proximity sensing circuit 90 controls the baseline processing circuit 84 to maintain the nth value of the baseline data BASE as the (n+1)th value (namely, Base[n+1]=Base[n]). Next, in the step S360, after generating the proximity signal Prox, the threshold processing circuit 100 corrects the proximity threshold THD according to the (n+1)th value (Ref[n+1]) and the nth value (Ref[n]) of the reference data REF and the nth value (THD[n]) of the proximity threshold THD for generating the (n+1)th value (THD[n+1]) of the proximity threshold THD. The above n is a positive integer greater than or equal to 1.

Next, in the step S380, acquire the next values (Raw[n+2], Ref[n+2]) of the detection data RAW and the reference data REF. Thereby, the (n+1)th value of the baseline data BASE maintained in the step S350 may continue to be adopted in the step S390 for generating the difference value SIGNAL. In addition, when the difference value SIGNAL is greater than the (n+1)th value (THD[n+1]) of the proximity threshold THD, generate the proximity signal Prox in the step S360. The above n is a positive integer greater than or equal to 1.

According to another embodiment of the present application, after the proximity sensing circuit 90 judges that the difference value SIGNAL is greater than the proximity threshold THD in the step S400, return to the step S350 for maintaining the baseline data BASE, generating the proximity signal Prox, and correcting the proximity threshold THD. After the proximity sensing circuit 90 judges that the difference value SIGNAL is smaller than the proximity threshold THD in the step S400, the baseline processing circuit 84 executes the step S412 for generating the current value (Base[n]) of the baseline data BASE according to the current value (Raw[n]) of the detection data RAW. According to another embodiment of the present application, the current value (Raw[n]) of the detection data RAW is used as the current value (Base[n]) of the baseline data BASE. In addition, correct the proximity threshold THD according to the preset value (REG_THD) of the detection data RAW. For example, the preset value (REG_THD) of the proximity threshold THD is used as the current value (THD[n]) of the proximity threshold THD, as expressed by Base[n]=RAW[n], THD[n]=REG_THD. The above n is a positive integer greater than or equal to 1. Next, in the step S320, acquire the next data of the detection data RAW and the reference data REF for generating the difference value SIGNAL.

According to another embodiment of the present application, in the step S400, after the proximity sensing circuit 90 judges that the difference value SIGNAL between the (n+1)th value of the detection data RAW and the nth value (Base[n]) of the baseline data BASE is smaller than the nth value (THD[n]) of the proximity threshold THD, execute the step S412 first for driving the baseline processing circuit 84 to use the (n+1)th value (Raw[n+1]) of the detection data RAW as the (n+1)th value (Base[n+1]) of the baseline data BASE. In addition, use the preset value (REG_THD) of the proximity threshold THD to correct the (n+1)th value (THD[n+1]) of the proximity threshold THD. Next, in the step S320, acquire the next values (Raw[n+2], Ref[n+2]) of the detection data RAW and the reference data REF. Thereby, the (n+1)th value (Base[n+1]) of the baseline data BASE acquired in the step S412 continues to be used in the step S330 for generating the difference value SIGNAL. When the step S340 judges that the difference value SIGNAL is greater than the nth value (THD[n]) of the proximity threshold THD, execute the step S350. The proximity sensing circuit 90 controls the baseline processing circuit 84 to maintain the (n+1)th value of the baseline data BASE as the (n+2)th value (namely, Base[n+2]=Base[n+1]). Next, in the step S360, generate the proximity signal Prox. The above n is a positive integer greater than or equal to 1.

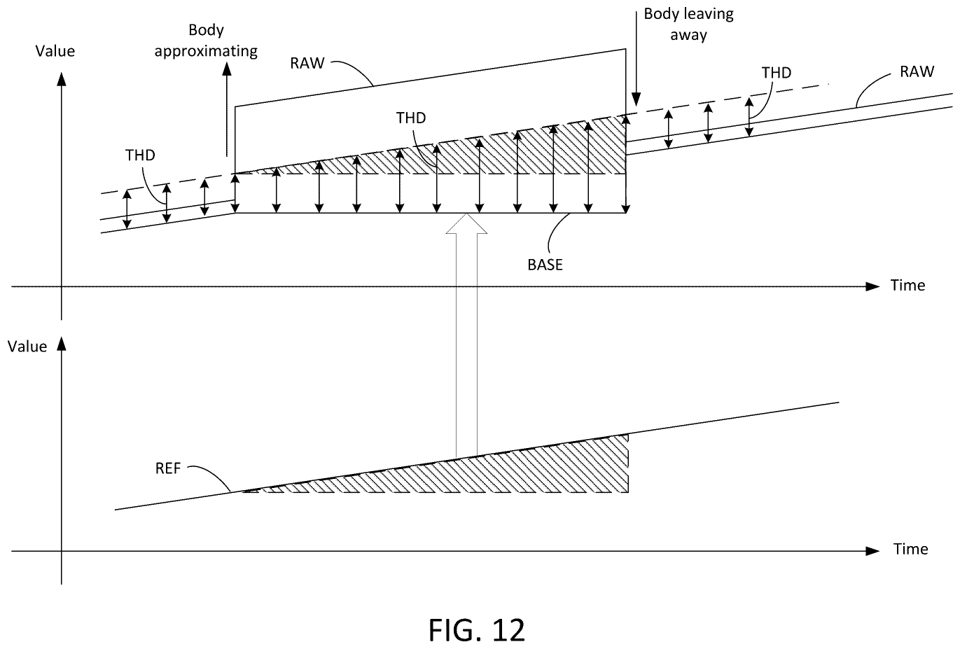

As shown in FIG. 12, when the proximity signal Prox is judged to be generated, correct the proximity threshold THD according to the current value (Ref[n]) and the previous value (Ref[n−1]) of the reference data REF and the previous value (THD[n−1]) of the proximity threshold THD and giving the current value (THD[n]) of the proximity threshold. In other words, the value of the proximity threshold THD changes according to the reference data REF corresponding to environmental factors. For example, when the temperature change or humidity change will lead to changes in the capacitance of the reference electrode. Then the value of the reference data REF will be changed accordingly. When the detection data RAW is increased due to environmental factors, the difference value between the detection data RAW and the baseline data BASE will be increased. Since proximity threshold THD is compensated according to the reference data REF, the proximity threshold THD is increased correspondingly for compensating the variation of the detection data RAW by the influence of environmental factors. When the object or the human body is away from the electronic device, the value of the detection data RAW is decreased. Besides, the difference value between the current decreased value of the detection data RAW and the baseline data BASE is smaller than the proximity threshold THD. Thereby, the object or the human body will be judged to be away from the electronic device. Accordingly, the misjudgments will be avoided.

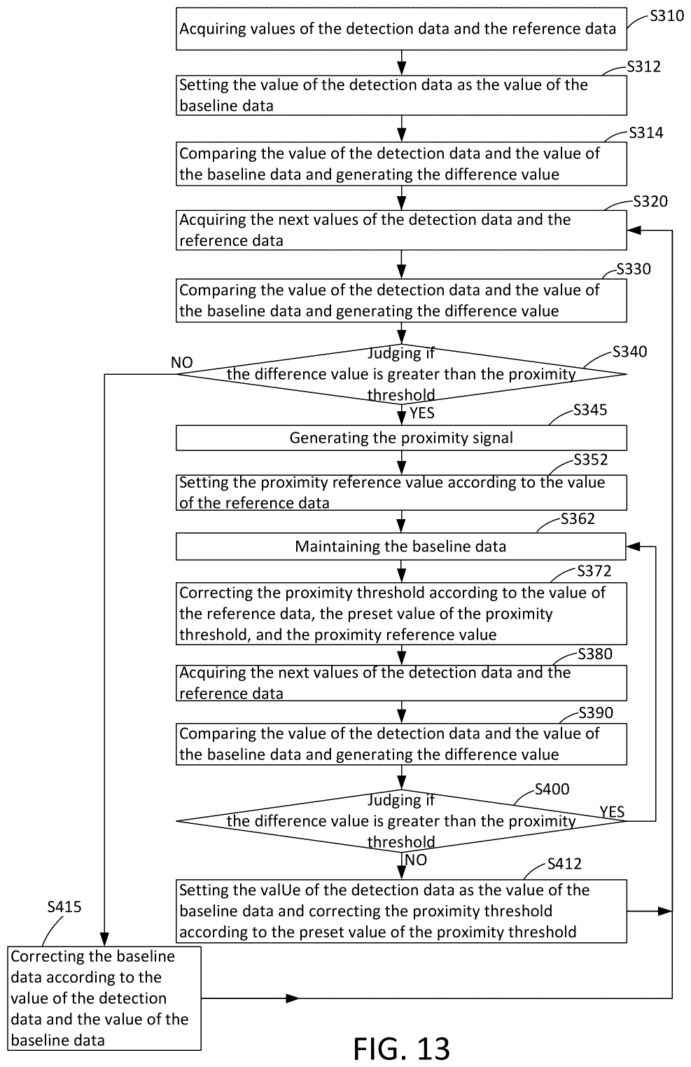

Please refer to FIG. 13, which shows a flowchart of the proximity detection method according to another embodiment of the present application. As shown in the figure, the method comprises steps of:
Step S310: Acquiring values of the detection data and the reference data;
Step S312: Setting the value of the detection data as the value of the baseline data;
Step S314: Comparing the value of the detection data with the value of the baseline data to generate the difference value;
Step S320: Acquiring the next values of the detection data and the reference data;
Step S330: Comparing the value of the detection data with the value of the baseline data to generate the difference value;
Step S340: Judging if the difference value is greater than the proximity threshold; and if yes, executing the step S350, otherwise the step S415;
Step S345: Generating the proximity signal;
Step S352: Setting the proximity reference value according to the value of the reference data;
Step S362: Maintaining the baseline data;
Step S372: Correcting the proximity threshold according to the value of the reference data, the preset value of the proximity threshold, and the proximity reference value;
Step S380: Acquiring the next values of the detection data and the reference data;
Step S390: Comparing the value of the detection data with the value of the baseline data to generate the difference value;
Step S400: Judging if the difference value is greater than the proximity threshold; and if yes, executing the step S350, otherwise the step S412;
Step S412: Using the value of the detection data as the value of the baseline data and correcting the proximity threshold according to the preset value; and
Step S415: Correcting the baseline data according to the value of the detection data and the value of the baseline data.

The steps S310 to S345 are identical to the steps S10 to S50 in FIG. 2. Hence, the details will not be repeated. The steps S380 to step S415 have been disclosed in the embodiment of FIG. 11. Hence, the details will not be repeated. The proximity sensing circuit 90 controls the threshold processing circuit 100 to execute the step S352 and sets the proximity reference value according to the value of the reference data REF. Next, in the step S362, the baseline processing circuit 84 is driven to maintain the baseline data BASE. The threshold processing circuit 100 executes the step S372 for correcting the proximity threshold THD according to the value of the reference data REF, the preset value of the proximity threshold THD, and the proximity reference value. Thereby, the corrected proximity threshold THD may be used to judge the difference value SIGNAL in the step S400. If the difference value SIGNAL is greater than the corrected proximity threshold THD, the step S362 is executed. Otherwise, the baseline processing circuit 84 and the threshold processing circuit 100 are driven to execute the step S412. The baseline processing circuit 84 uses the value of the detection data RAW as the value of the baseline data BASE. The threshold processing circuit 100 corrects the proximity threshold THD according to the preset value REG_THD of the proximity threshold THD.

According to another embodiment of the present application, in the step S340, when the proximity sensing circuit 90 judges that the difference value SIGNAL is greater than the proximity threshold THD, the threshold processing circuit 100 sets the proximity reference value (prox_ref0) according to value of the reference data REF. According to an embodiment of the present application, the threshold processing circuit 100 sets the proximity reference value (prox_ref0) according to the previous value (Ref[n−1]) of the reference data REF. Next, in the step S362, the baseline processing circuit 84 is driven to use the previous value (Base[n−1]) of the baseline data BASE as the current value (Base[n]) of the baseline data BASE. Then, in the step S372, the threshold processing circuit 100 corrects the proximity threshold THD according to the current value (Ref[n]) of the reference data REF, the preset value (REG_THD) of the proximity threshold THD, and the proximity reference value (prox_ref0) and gives the current value (THD[n]) of the proximity threshold THD, which may expressed as THD[n]=REG_THD+G*(Ref[n]−prox_ref0). G is set according to the characteristic (for example, ratio) of the sensing electrode 202 and the reference electrode 222; and n is a positive integer greater than or equal to 0.

According to another embodiment of the present application, in the step S400, when the proximity sensing circuit 90 judges that the difference value SIGNAL is greater than the nth value (THD[n]) of the proximity threshold THD, return to the step S362 for driving the baseline processing circuit 84 to use the nth value (Base[n]) of the baseline data BASE as the (n+1)th value (Base[n+1]) of the baseline data BASE. Then, in the step S372, the threshold processing circuit 100 corrects the proximity threshold THD according to the (n+1)th value (Ref[n+1]) of the reference data REF, the preset value (REG_THD) of the proximity threshold THD, and the proximity reference value (prox_ref0) and giving the (n+1)th value (THD[n+1]) of the proximity threshold THD. Next, in the step S380, acquire the next values (Raw[n+2], Ref[n+2]) of the detection data RAW and the reference data REF. The (n+1)th value (Base[n+1]) of the baseline data BASE acquired in the step S362 is used in the step S390 for generating the difference value SIGNAL. In the step S400, judge if the difference value SIGNAL is greater than the (n+1)th value (THD[n+1) of the proximity threshold THD. Then in the step S360, generate the proximity signal Prox for representing the occurrence of a proximity event. The above n is a positive integer greater than or equal to 0.

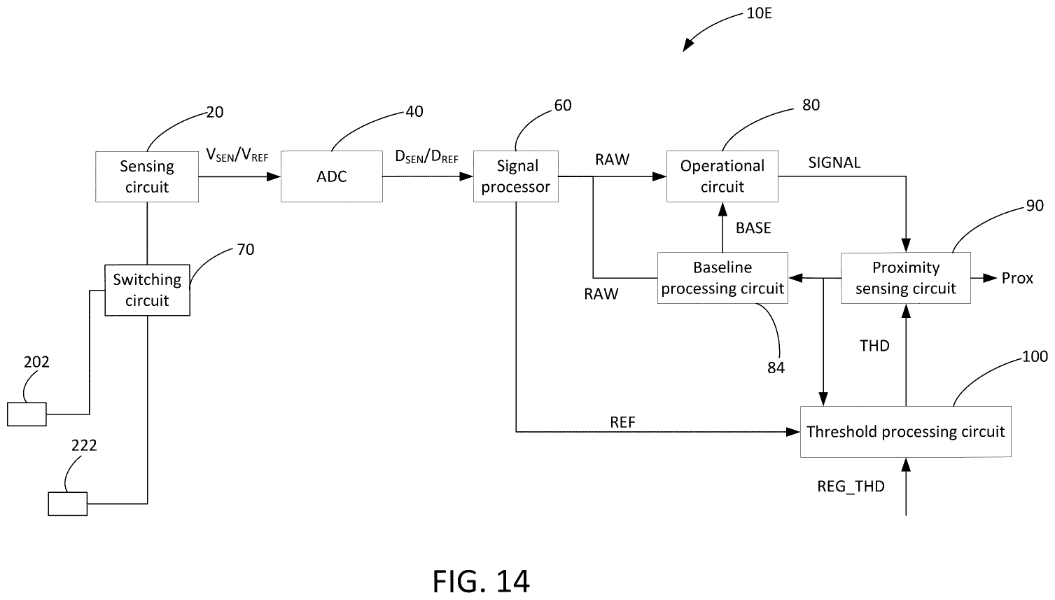

Please refer to FIG. 14, which shows a block diagram of the proximity detection circuit according to another embodiment of the present application. The difference between FIG. 10 and FIG. 14 is that the proximity detection circuit 10E in FIG. 14 further comprises a switching circuit 70; the sensing electrode 202 and the reference electrode 222 are coupled to the sensing circuit 20 via the switching circuit 70 by time division. Thereby, the corresponding sensing signal VSEN and the reference signal VREF may be generated by time division. The analog-to-digital converter 40 generates the corresponding sensing digital signal DSEN and the reference digital signal DREF by time division. The signal processor 60 generates the corresponding detection data RAW and the reference data REF by time division. The rest connections and operating principles are identical to the proximity detection circuit 10D in FIG. 10. Hence, the details will not be repeated.

According to the above embodiments, the operational circuit 80, the baseline processing circuit 84, and the threshold processing circuit 100 may be further integrated in the proximity sensing circuit 90. The circuit schemes such as SOC or FPGA may be used to implement the proximity detection circuits 10D, 10E and adjusted according to requirements.

To sum up, the present application provides a proximity detection circuit and a proximity detection method with compensation. The proximity signal is generated according to the detection data, the baseline data, and the proximity threshold for detecting proximity events. The baseline data or the proximity threshold is corrected according to the reference data corresponding to environmental factors. Namely, the detection data will be influenced the environmental factors and hence compensating the baseline data or the proximity threshold. Thereby, even under the influence of environmental factors, misjudgments may still be avoided and thus improving the accuracy of proximity sensing.

Accordingly, the present application conforms to the legal requirements owing to its novelty, nonobviousness, and utility. However, the foregoing description is only embodiments of the present application, not used to limit the scope and range of the present application. Those equivalent changes or modifications made according to the shape, structure, feature, or spirit described in the claims of the present application are included in the appended claims of the present application.

1. A proximity detection method with compensation, comprising:
detecting a reference electrode and generating a reference data;
generating a proximity signal according to a detection data, a baseline data, and a proximity threshold; and
correcting said baseline data according to said reference data.

2. The proximity detection method of claim 1, further comprising:
comparing a value of said detection data with a value of said baseline data to generate a difference value, wherein said proximity signal is generated when said difference value is greater than said proximity threshold.

3. The proximity detection method of claim 1, further comprising:
generating an nth value of said baseline data according to an nth value and an (n−1)th value of said reference data and an (n−1)th value of said baseline data, wherein n is a positive integer greater than or equal to 1.

4. The proximity detection method of claim 1, further comprising:
setting a proximity reference value according to a value of said reference data;
setting a proximity baseline value according to a value of said baseline data; and
generating an nth value of said baseline data according to said proximity baseline value, an nth value of said reference data, and said proximity reference value;
wherein n is a positive integer greater than or equal to 1.

5. The proximity detection method of claim 4, further comprising:
comparing an (n+1)th value of said detection data with said nth value of said baseline data to generate a difference value, wherein said proximity signal is generated when said difference value is greater than said proximity threshold;
generating an (n+1)th value of said baseline data according to said proximity baseline value, an (n+1)th value of said reference data, and said proximity reference value; and
comparing an (n+2)th value of said detection data with said (n+1)th value of said baseline data to generate a difference value, wherein said proximity signal is generated when said difference value is greater than said proximity threshold.

6. The proximity detection method of claim 4, further comprising:
comparing an (n+1)th value of said detection data with said nth value of said baseline data to generate a difference value for generating an (n+1)th value of said baseline data according to said (n+1)th value of said detection data and said nth value of said baseline data when said difference value is smaller than said proximity threshold; and
comparing an (n+2)th value of said detection data with said (n+1)th value of said baseline data to generate a difference value for generating said proximity signal when said difference value is greater than said proximity threshold.

7. The proximity detection method of claim 1, further comprising:
comparing a value of said detection data with a value of said baseline data to generate a difference value, wherein said baseline data is generated according to said detection data and said baseline data when said difference value is smaller than said proximity threshold.

8. The proximity detection method of claim 1, further comprising:
generating said baseline data according to said reference data; and
comparing a value of said detection data with a value of said baseline data to generate a difference value, wherein said baseline data is generated according to said reference data when said difference value is smaller than said proximity threshold.

9. The proximity detection method of claim 1, further comprising:
generating said baseline data according to said reference data; and
comparing a value of said detection data with a value of said baseline data to generate a difference value, wherein said proximity signal is generated when said difference value is greater than said proximity threshold.

10. A proximity detection circuit with compensation, comprising:
a detection circuit, generating a detection data and a reference data;
a baseline processing circuit, coupled to said detection circuit, generating a baseline data, and correcting said baseline data according to said reference data; and
a proximity sensing circuit, coupled to said baseline processing circuit, and generating a proximity signal according to said detection data, said baseline data, and a proximity threshold.

11. The proximity detection circuit of claim 10, wherein said detection circuit detects a reference electrode and generates said reference data, and said baseline processing circuit generates said baseline data according to said detection data.

12. The proximity detection circuit of claim 10, further comprising an operational circuit, coupled to said detection circuit, said baseline processing circuit, and said proximity sensing circuit; said operational circuit comparing a value of said detection data with a value of said baseline data to generate a difference value, said proximity sensing circuit generating said proximity signal when said proximity sensing circuit judges that said difference value is greater than said proximity threshold.

13. The proximity detection circuit of claim 10, wherein said baseline processing circuit generates an nth value of said baseline data according to an (n−1)th value of said baseline data and an (n−1)th value and an nth value of said reference data, wherein said n is a positive integer greater than or equal to 1.

14. The proximity detection circuit of claim 10, further comprising an operational circuit, coupled to said detection circuit, said baseline processing circuit, and said proximity sensing circuit, said operational circuit comparing a value of said detection data with a value of said baseline data to generate a difference value, said baseline processing circuit generating said baseline data according to said baseline data and said detection data when said difference value is smaller than said proximity threshold.

15. The proximity detection circuit of claim 10, wherein said baseline processing circuit sets a proximity reference value according to a value of said reference data and sets a proximity baseline value according to a value of said baseline data, said baseline processing circuit generates an nth value of said baseline data according to said proximity baseline value, an nth value of said reference data, and said proximity reference value; and n is a positive integer greater than or equal to 1.

16. The proximity detection circuit of claim 15, further comprising an operational circuit, coupled to said detection circuit, said baseline processing circuit, and said proximity sensing circuit; said operational circuit comparing an nth value of said detection data with an (n−1)th value of said baseline data to generate a difference value, said baseline processing circuit generating said nth value of said baseline data according to said nth value of said reference data, said proximity reference value, and said proximity baseline value when said proximity sensing circuit judges that said difference value is greater than said proximity threshold and generates said proximity signal.

17. The proximity detection circuit of claim 15, further comprising an operational circuit, coupled to said detection circuit, said baseline processing circuit, and said proximity sensing circuit, said operational circuit comparing an (n+1)th value of said detection data with said nth value of said baseline data to generate a difference value, said proximity sensing circuit generating said proximity signal when said proximity sensing circuit judges that said difference value is greater than said proximity threshold, said baseline processing circuit generating an (n+1)th value of said baseline data according to said proximity baseline value, an (n+1)th value of said reference data, and said proximity reference value, and said operational circuit comparing an (n+2)th value of said detection data with said (n+1)th value of said baseline data to generate a difference value, said proximity sensing circuit generating said proximity signal when said difference value is greater than said proximity threshold.

18. The proximity detection circuit of claim 15, further comprising an operational circuit, coupled to said detection circuit, said baseline processing circuit, and said proximity sensing circuit, said operational circuit comparing an (n+1)th value of said detection data with said nth value of said baseline data to generate a difference value, said baseline processing circuit generating an (n+1)th value of said baseline data according to said (n+1)th value of said detection data and said nth value of said baseline data when said difference value is smaller than said proximity threshold; said operational circuit comparing an (n+2)th value of said detection data with said (n+1)th value of said baseline data to generate a difference value, said proximity sensing circuit generating said proximity signal when said difference value is greater than said proximity threshold.

19. The proximity detection circuit of claim 10, further comprising an operational circuit, said baseline processing circuit generating said baseline data according to said reference data, said operational circuit comparing a value of said detection data with a value of said baseline data to generate a difference value, said baseline processing circuit generating said baseline data according to said reference data when said proximity sensing circuit judges that said difference value is smaller than said proximity threshold.

20. The proximity detection circuit of claim 10, further comprising an operational circuit, said baseline processing circuit generating said baseline data according to said reference data, said operational circuit comparing a value of said detection data with a value of said baseline data to generate a difference value, said baseline processing circuit generating said baseline data according to said reference data and said proximity sensing circuit generating said proximity signal when said proximity sensing circuit judges that said difference value is greater than said proximity threshold.

21. A proximity detection method with compensation, comprising:
detecting a reference electrode and generating a reference data;
generating a proximity signal according to a detection data, a baseline data, and a proximity threshold; and
correcting said proximity threshold according to said reference data.

22. The proximity detection method of claim 21, further comprising:
comparing a value of said detection data with a value of said baseline data to generate a difference value, wherein said proximity signal is generated and said baseline data is maintained when said difference value is greater than said proximity threshold.

23. The proximity detection method of claim 21, further comprising:
comparing a value of said detection data with a value of said baseline data to generate a difference value, wherein said baseline data is generated according to said detection data and said baseline data when said difference value is smaller than said proximity threshold.

24. The proximity detection method of claim 21, further comprising:
generating an nth value of said proximity threshold according to an (n−1)th value of said proximity threshold and an (n−1)th value and an nth value of said reference data, wherein n is a positive integer greater than or equal to 1.

25. The proximity detection method of claim 24, further comprising:
comparing an (n+1)th value of said detection data with an nth value of said baseline data to generate a difference value, wherein said proximity signal is generated when said difference value is greater than said nth value of said proximity threshold;
maintaining the value of said baseline data;
generating an (n+1)th value of said proximity threshold according to said nth value of said proximity threshold and said nth value and an (n+1)th value of said reference data; and
comparing an (n+2)th value of said detection data with said value of said baseline data to generate a difference value, wherein said proximity signal is generated when said difference value is greater than said (n+1)th value of said proximity threshold.

26. The proximity detection method of claim 24, further comprising:
comparing an (n+1)th value of said detection data with an nth value of said baseline data to generate a difference value, wherein an (n+1)th value of said baseline data is generated according to said (n+1)th value of said detection data, and correcting said proximity threshold according to a preset value when said difference value is smaller than said nth value of said proximity threshold.

27. The proximity detection method of claim 21, further comprising:
setting a proximity reference value according to a value of said reference data; and
generating an nth value of said proximity threshold according to a preset value of said proximity threshold, an nth value of said reference data, and said proximity reference value;
wherein n is a positive integer greater than or equal to 1.

28. The proximity detection method of claim 27, further comprising:
comparing an (n+1)th value of said detection data with an nth value of said baseline data to generate a difference value, wherein said proximity signal is generated when said difference value is greater than said nth value of said proximity threshold;
maintaining the value of said baseline data;
generating an (n+1)th value of said proximity threshold according to said preset value of said proximity threshold, an (n+1)th value of said reference data, and said proximity reference value; and
comparing an (n+2)th value of said detection data with said value of said baseline data to generate a difference value, wherein said proximity signal is generated when said difference value is greater than said (n+1)th value of said proximity threshold.

29. The proximity detection method of claim 27, further comprising:
comparing an (n+1)th value of said detection data with an nth value of said baseline data to generate a difference value, wherein an (n+1)th value of said baseline data is generated according to said (n+1)th value of said detection data, and correcting said proximity threshold according to said preset value when said difference value is smaller than said nth value of said proximity threshold.

30. A proximity detection circuit with compensation, comprising:
a detection circuit, generating a detection data and a reference data;
a baseline processing circuit, coupled to said detection circuit, and generating a baseline data according to said detection data;
a threshold processing circuit, coupled to said detection circuit, and generating a proximity threshold according to said reference data; and
a proximity sensing circuit, coupled to said baseline processing circuit and said threshold processing circuit, and generating a proximity signal according to said detection data, said baseline data, and said proximity threshold.

31. The proximity detection circuit of claim 30, further comprising an operational circuit, coupled to said detection circuit, said baseline processing circuit, and said proximity sensing circuit, said operational circuit comparing a value of said detection data with a value of said baseline data to generate a difference value, said proximity sensing circuit generating said proximity signal and said baseline processing circuit maintaining said baseline data when said proximity sensing circuit judges that said difference value is greater than said proximity threshold.

32. The proximity detection circuit of claim 30, further comprising an operational circuit, coupled to said detection circuit, said baseline processing circuit, and said proximity sensing circuit; said operational circuit comparing a value of said detection data with a value of said baseline data to generate a difference value, said baseline processing circuit generating said baseline data according to said baseline data and said detection data when said difference value is smaller than said proximity threshold.

33. The proximity detection circuit of claim 30, wherein said threshold processing circuit generates an nth value of said proximity threshold according to an (n−1)th value of said proximity threshold and an (n−1)th value and an nth value of said reference data, and n is a positive integer greater than or equal to 1.

34. The proximity detection circuit of claim 33, further comprising an operational circuit, coupled to said detection circuit, said baseline processing circuit, and said proximity sensing circuit; said operational circuit comparing an (n+1)th value of said detection data with an nth value of said baseline data to generate a difference value, said baseline processing circuit maintaining said value of said baseline data when said proximity sensing circuit judges that said difference value is greater than said nth value of said proximity threshold and generates said proximity signal, said threshold processing circuit generating an (n+1)th value of said proximity threshold according to said nth value of said proximity threshold and said nth value and an (n+1)th value of said reference data, said operational circuit comparing an (n+2)th value of said detection data with said value of said baseline data and generating a difference value, said proximity sensing circuit generating said proximity signal when said difference value is greater than said (n+1)th value of said proximity threshold.

35. The proximity detection circuit of claim 33, further comprising an operational circuit, coupled to said detection circuit, said baseline processing circuit, and said proximity sensing circuit; said operational circuit comparing an (n+1)th value of said detection data with an nth value of said baseline data to generate a difference value, said baseline processing circuit generating an (n+1)th value of said baseline data according to said (n+1)th value of the detection data when said difference value is smaller than said nth value of said proximity threshold, and said threshold processing circuit correcting said proximity threshold according to a preset value.

36. The proximity detection circuit of claim 30, wherein said threshold processing circuit sets a proximity reference value according to a value of said reference data, and generates an nth value of said proximity threshold according to a preset value of said proximity threshold, an nth value of said reference data, and said proximity reference value, and n is positive integer greater than or equal to 1.

37. The proximity detection circuit of claim 36, further comprising an operational circuit, coupled to said detection circuit, said baseline processing circuit, and said proximity sensing circuit; said operational circuit comparing an (n+1)th value of said detection data with an nth value of said baseline data to generate a difference value, said baseline processing circuit maintaining said value of said baseline data when said proximity sensing circuit judges that said difference value is greater than said nth value of said proximity threshold and generates said proximity signal, said threshold processing circuit generating an (n+1)th value of said proximity threshold according to said preset value of said proximity threshold, an (n+1)th value of said reference data, and said proximity reference value; said operational circuit comparing an (n+2)th value of said detection data with said value of said baseline data and generating a difference value, said proximity sensing circuit generating said proximity signal when said difference value is greater than said (n+1)th value of said proximity threshold.

38. The proximity detection circuit of claim 36, further comprising an operational circuit, coupled to said detection circuit, said baseline processing circuit, and said proximity sensing circuit, said operational circuit comparing an (n+1)th value of said detection data with an nth value of said baseline data to generate a difference value, said baseline processing circuit generating an (n+1)th value of said baseline data according to said (n+1)th value of said detection data when said difference value is smaller than said nth value of said proximity threshold, and said threshold processing circuit correcting said proximity threshold according to said preset value.

39. The proximity detection circuit of claim 30, wherein said detection circuit detects a reference electrode and generates said reference data, and said detection circuit detects a sensing electrode and generates said detection data.
